(19) United States
(12) Patent Application Publication
(10) Pub. No.: US 2018/0337101 A1
(43) Pub. Date: Nov. 22, 2018

(54) SEMICONDUCTOR STRUCTURES AND FABRICATION METHODS THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 15/984,147

(22) Filed: May 18, 2018

(30) Foreign Application Priority Data
May 19, 2017 (CN) 201710355120.7

(51) Int. Cl. H01L 21/8238; H01L 21/762; H01L 21/225; H01L 21/311; H01L 21/02; H01L 29/66; H01L 29/36; H01L 29/167; H01L 21/265; H01L 29/06; H01L 29/08; H01L 27/092; H01L 21/324

(52) U.S. Cl. CPC H01L 21/823878; H01L 21/31053; H01L 21/823814; H01L 21/2255; H01L 21/823821; H01L 21/31116; H01L 21/0217; H01L 21/0214; H01L 21/823864; H01L 29/6656; H01L 29/36; H01L 29/167; H01L 21/26513; H01L 29/0649; H01L 29/0847; H01L 27/0924; H01L 21/324; H01L 21/02271; H01L 21/0228; H01L 21/76224

(57) ABSTRACT

A method for fabricating a semiconductor structure includes forming an isolation structure on a base substrate including a first region and a second region, forming a protective layer on the base substrate in the second region and on the isolation structure in the second region, forming a doped layer on the base substrate in the first region and on the protective layer in the second region, performing an annealing process on the doped layer to allow doping ions in the doped layer to diffuse into the first region of the base substrate and thus form a first doped region the first region of the base substrate, and removing the doped layer after performing the annealing process.

### CROSS-REFERENCES TO RELATED APPLICATIONS

This application claims the priority of Chinese Patent Application No. CN201710355120.7, filed on May 19, 2017, the entire content of which is incorporated herein by reference.

### FIELD OF THE DISCLOSURE

The present disclosure generally relates to the field of semiconductor fabrication technology and, more particularly, relates to semiconductor structures and their fabrication methods.

### BACKGROUND

With the improvement of the integration degree of semiconductor devices, the critical dimension of transistors continuously shrinks, the width of gate structure decreases, and thus the length of the channel below the gate structure is reduced. The reduction of the channel length in the transistor increases the charge-penetration possibility between the source doped region and the drain doped region, which easily induces a leakage current in the channel.

The gate structure of a fin field-effect transistor (Fin-FET) is similar to a fin of fish with a fork-like three dimensional (3D) structure. The channel of a Fin-FET protrudes from the surface of substrate and form a fin structure, and the gate structure covers the top and the sidewall surfaces of the fin structure, such that turning on and off the channel can be realized through a control from the two sides of the fin structure.

In order to meet the requirements for further improving the integration degree of semiconductor devices, the length of the channel under the gate structure of a Fin-FET may be further reduced. To reduce the leakage current in the channel, a solid source doping process is introduced into the fabrication process of semiconductor structures to form a lightly doped region in the substrate and thus reduce the leakage current in the channel.

However, the existing solid source doping process may easily lead to poor isolation properties for the isolation structure in the formed Fin-FET device, and thus cause undesired performance of the semiconductor structure. The disclosed semiconductor structures and fabrication methods are directed to solve one or more problems set forth above and other problems in the art.

### BRIEF SUMMARY OF THE DISCLOSURE

One aspect of the present disclosure includes a method for fabricating a semiconductor structure. The method includes forming an isolation structure on a base substrate including a first region and a second region, forming a protective layer on the base substrate in the second region and on the isolation structure in the second region, forming a doped layer on the base substrate in the first region and on the protective layer in the second region, performing an annealing process on the doped layer to allow doping ions in the doped layer to diffuse into the first region of the base substrate and thus form a first doped region in the first region of the base substrate, and removing the doped layer after performing the annealing process.

Another aspect of the present disclosure provides a semiconductor structure. The semiconductor structure includes a base substrate including a first region and a second region, an isolation structure formed on the base substrate, a first doped region formed in the base substrate in the first region, a protective layer formed on the base substrate and the isolation structure in the second region, and a second doped region formed in the base substrate in the second region.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-2 illustrate schematic cross-section views of semiconductor structures at certain stages of a fabrication process;

FIGS. 3-13 illustrate schematic cross-section views of semiconductor structures at certain stages of an exemplary fabrication process for a semiconductor structure consistent with various embodiments of the present disclosure; and

FIG. 14 illustrates a flowchart of an exemplary method for fabricating a semiconductor structure consistent with various embodiments of the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

When fabricating semiconductor structures, isolation structures in the formed semiconductor structure may not be able to provide desirable isolation properties, which further affects the performance of the semiconductor structure.

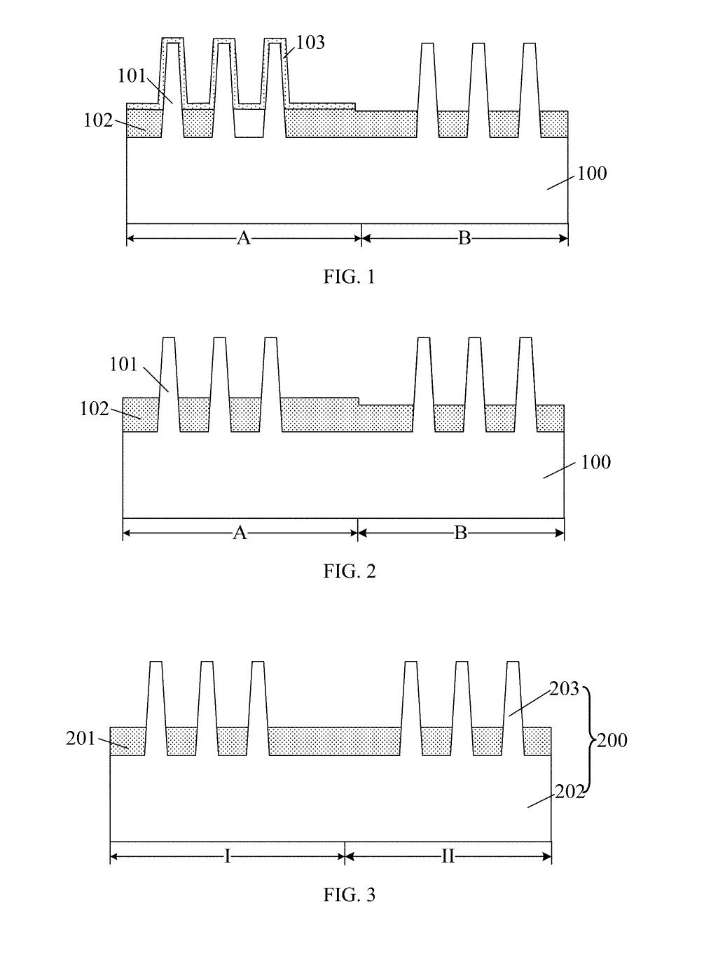

FIGS. 1-2 show schematic cross-section views of semiconductor structures at certain stages of a fabrication process.

Referring to FIG. 1, a base substrate is provided. A first region A and a second region B are defined on the base substrate. The base substrate includes a substrate 100 and a plurality of fin structures 101 formed on the substrate 100 in both the first region A and the second region B. An isolation structure 102 is formed on the base substrate. The isolation structure 102 covers a portion of the sidewall surfaces of each fin structure 101, and has a top surface lower than the top surface of the plurality of fin structures 101. In addition, a doped layer 103 is formed on the portion of the base substrate in the first region A. The doped layer 103 contains doped ions.

The doped layer 103 is formed through the following steps. An initial doped layer is formed on the base substrate in both the first region A and the second region B. The portion of the initial doped layer formed on the base substrate of the second region B is then removed to form the doped layer 103.

Further, an annealing process is performed on the doped layer 103 so that the doped ions in the doped layer 103 can diffuse into the fin structures 101 in the first region and thus form a lightly-doped region.

Referring to FIG. 2, after the annealing process, the doped layer 103 (referring to FIG. 1), i.e., the portion of the initial doped layer formed on the portion of the base substrate in the first region A, is removed.

According to the fabrication process described above, during the process to form the doped layer 103, the portion of the initial doped layer formed on the base substrate of the second region B needs to be removed. The removal of the portion of the initial doped layer formed on the base substrate of the second region B may cause first-time damage to the isolation structure 102 formed on the base substrate of the second region B. Further, the doped layer 103 may be removed after an annealing process is performed, and the removal of the doped layer 103 may not be completed until the isolation structure 102 formed in the first region A is fully exposed. Therefore, the process to remove the doped layer 103 may cause second-time damage to the isolation structure formed on the base substrate of the second region B, and the second-time damage to the isolation structure 102 of the second region B may even be more severe than the first-time damage. As such, the isolation structure 102 may be damaged twice so that the thickness of the portion of the isolation structure 102 formed in the second region B may be smaller than the thickness of the portion of the isolation structure 102 formed in the first region A. Therefore, the isolation properties of the portion of the isolation structure 102 formed in the second region B may be poor, which may affect the performance of the semiconductor structure.

The present disclosure provides a method for fabricating semiconductor structures to improve the isolation properties of the isolation structure in the formed semiconductor structure. FIG. 14 shows a flowchart of an exemplary method for fabricating a semiconductor structure consistent with various embodiments of the present disclosure. FIGS. 3-13 show schematic cross-section views of semiconductor structures at certain stages of the exemplary fabrication process.

Referring to FIG. 14, at the beginning of the fabrication process, a base substrate including a first region and a second region may be provided, and an isolation structure may be formed on the base substrate (S401). FIG. 3 shows a schematic cross-section view of a corresponding semiconductor structure.

Referring to FIG. 3, a base substrate 200 may be provided. A first region I and a second region II may be defined on the base substrate 200. An isolation structure 201 may be formed on the base substrate 200.

In one embodiment, the first region I may be used to form N-type metal-oxide-semiconductor (NMOS) transistors, and the second region II may be used to form P-type metal-oxide-semiconductor (PMOS) transistors, or vice versa.

The base substrate 200 may include a substrate 202 and a plurality of fin structures 203 formed on the substrate 202.

The base substrate 200 may be formed by a process including providing an initial substrate and then patterning the initial substrate to form the substrate 202 and the plurality of fin structures 203 on the substrate 202.

In one embodiment, the initial substrate is made of silicon. In other embodiments, the initial substrate may be made of germanium, SiGe, silicon on insulator (SOI), germanium on insulator (GOI), or any other appropriate semiconductor material or structure.

The isolation structure 201 may be formed by a process including the following exemplary steps. An isolation material layer may be formed on the substrate 202 and the plurality of fin structures 203. A chemical mechanical polishing (CMP) process may then be performed to planarize the isolation material layer. Further, a portion of the isolation material layer may be removed through an etching process to form the isolation structure 201. The isolation structure 201 may be formed on the portion of the substrate 202 between neighboring fin structures 203. The isolation structure 201 may cover a portion of the sidewall surfaces of each fin structure 203, and the top surface of the isolation layer 201 may be lower than the top surface of the fin structures 203.

In one embodiment, the method to form the isolation material layer may include chemical vapor deposition (CVD) process, and the isolation structure 201 may be made of a material including SiOₓ. In other embodiments, the isolation structure may be made of SiON, SiNₓ, or any other appropriate material.

The isolation structure 201 may be used to electrically isolate neighboring semiconductor devices.

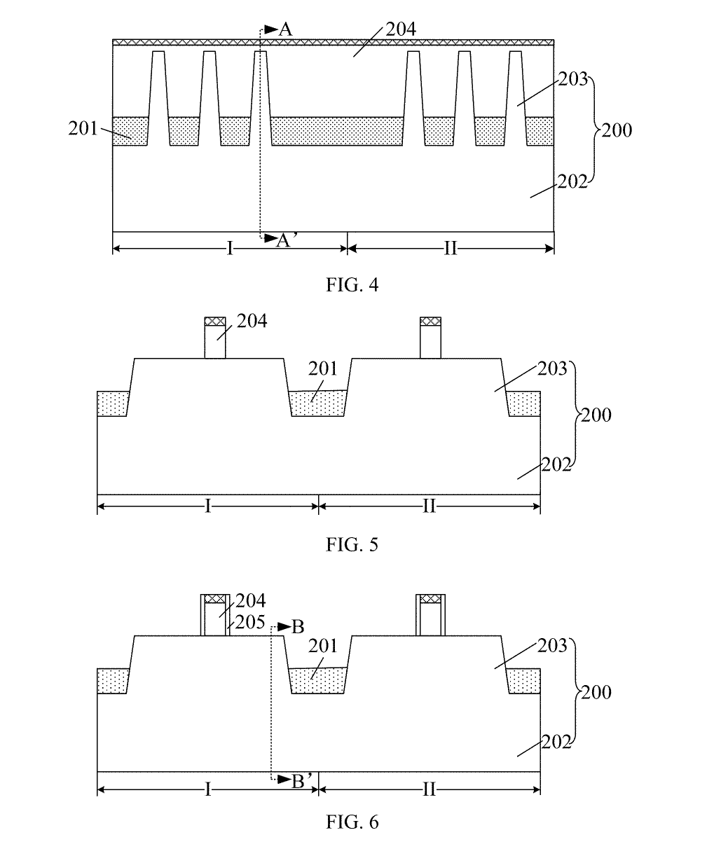

Returning to FIG. 14, a gate structure may be formed on the base substrate across the fin structures (S402). FIGS. 4-5 show schematic cross-section views of a corresponding semiconductor structure. Specifically, FIG. 5 shows a schematic cross-section view of the semiconductor structure shown in FIG. 4 in an A-A′ direction.

Referring to FIGS. 4-5, a gate structure 204 may be formed on the base substrate 200 across the plurality of fin structures 203. In one embodiment, the gate structure 204 may include a gate dielectric layer and a gate electrode layer formed on the gate dielectric layer. The gate dielectric layer may cover a portion of the top and the sidewall surfaces of each fin structure 203, and the gate electrode layer may be formed on the surface of the gate dielectric layer.

In one embodiment, the gate dielectric layer is made of SiOₓ. In other embodiments, the gate dielectric layer may be made of SiNₓ, SiON, or any other appropriate dielectric material.

In one embodiment, the gate electrode layer is made of poly-crystalline silicon. In other embodiments, the gate electrode layer may be a metal gate electrode layer. That is, the gate electrode layer may be made of a metal.

In one embodiment, a mask layer (not shown) may be formed on the top surface of the gate structure 204. The mask layer may be made of a material including SiNₓ. The mask layer may serve as an etch mask during an etching process to form the gate electrode layer.

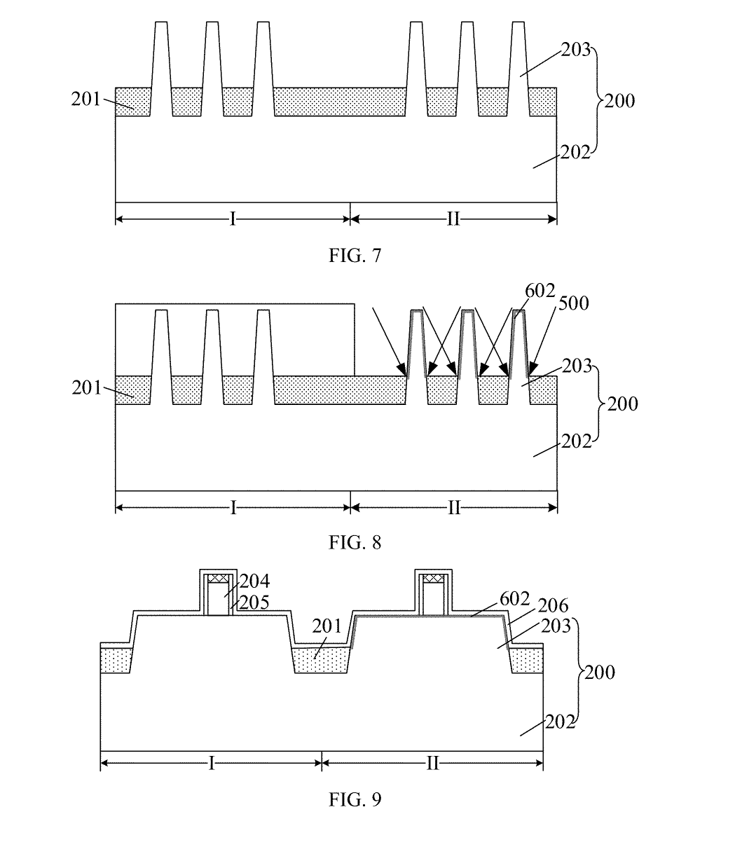

Further, returning to FIG. 14, a gate sidewall spacer may be formed on each sidewall surface of the gate structure (S403). FIGS. 6-7 show schematic cross-section views of a corresponding semiconductor structure. Specifically, FIG. 7 shows a schematic cross-section view of the semiconductor structure shown in FIG. 6 in a B-B′ direction. The cross-section view shown in FIG. 6 is in a same direction as the cross-section view shown in FIG. 5, and the semiconductor structure shown in FIG. 6 is developed from the semiconductor structure shown in FIG. 5.

Referring to FIGS. 6-7, a gate sidewall spacer 205 may be formed on each sidewall surface of the gate structure 204.

The gate sidewall spacer 205 may be formed by a process including the following exemplary steps. A gate sidewall spacer film may be formed on the sidewall surfaces of the gate dielectric layer, the top and the sidewall surfaces of the gate electrode layer, and the top surface of each fin structure 203 on both sides of the gate electrode layer. The portion of the gate sidewall spacer film formed on the top surface of the gate electrode layer and also on the top surface of each fin structure 203 on both sides of the gate electrode layer may then be removed to form the gate sidewall spacer 205.

The gate sidewall spacer film may be formed by a process including CVD. The gate sidewall spacer film and the gate sidewall spacer 205 may be made of a same material. In one embodiment, the gate sidewall spacer film is made of a material including SiNₓ.

The gate sidewall spacer 205 may be used to define the relative positions of subsequently-formed source/drain doped regions with respect to the gate structure 204.

The process to remove the portion of the gate sidewall spacer film formed on the top surface of the gate electrode layer and also on the top surface of each fin structure 203 on both sides of the gate electrode layer may include a dry etching process and/or a wet etching process.

Further, returning to FIG. 14, a second doped region may be formed in the base substrate of the second region (S404). FIG. 8 shows a schematic cross-section view of a corresponding semiconductor structure. Specifically, the cross-section view shown in FIG. 8 is in a same direction as the cross-section view shown in FIG. 7.

Referring to FIG. 8, a second doped region 602 may be formed in the base substrate 200 of the second region II.

In one embodiment, a first doped region may be formed in the base substrate 200 of the first region I, as described in FIG. 12. The second doped region 602 formed in the base substrate 200 of the second region II may be a lightly doped region. The second doped region 602 may be formed in a portion of each fin structure 203, e.g., having a thickness from each sidewall of the fin structure 203. The second doped region 602 may be formed into each fin structure 203 including the portion lower than a surface of the isolation structure 201. In some embodiments, the fin structures 203 may be entirely doped to form the second doped region 602.

In one embodiment, the second doped region 602 may be formed by a process including the following exemplary steps. A patterned layer may be formed on the base substrate 200 of the first region I. After forming the patterned layer to cover the base substrate 200 of the first region I, an ion implantation process 500 may be performed to implant doping ions into the base substrate 200 of the second region II to form the second doped region 602.

In one embodiment, the second doped region 602 may be formed prior to forming the first doped region. Alternatively, the second doped region may be formed after forming the first doped region.

In one embodiment, the second doped region 602 is formed through an ion implantation process 500. In other embodiments, the second doped region may be formed by a process including the following exemplary steps. A doped layer may be formed on the base substrate of the second region. After forming the doped layer, an annealing process may be performed on the doped layer to allow the doping ions in the doped layer to diffuse into the base substrate of the second region, and thus form a second doped region.

Further, returning to FIG. 14, an initial protective layer may be formed on the base substrate and the isolation structure (S405). FIG. 9 shows a schematic cross-section view of a corresponding semiconductor structure. Specifically, the cross-section view shown in FIG. 9 is in a same direction as the cross-section view shown in FIG. 6.

Referring to FIG. 9, an initial protective layer 206 may be formed on the base substrate 200 and the isolation structure 201. In one embodiment, a gate structure 204 is formed on the surface of the base substrate 200. Accordingly, the initial protective layer 206 may also cover the top and the sidewall surfaces of the gate structure 204.

In one embodiment, the initial protective layer 206 may be formed by a CVD, physical vapor deposition (PVD), atomic layer deposition (ALD), or any other appropriate deposition process.

In one embodiment, the initial protective layer 206 is made of SiNₓ. In other embodiments, the initial protective layer may be made of SiOₓ, SiON, germanium oxide, GeON, germanium nitride, or any other appropriate material. Alternatively, the initial protective layer may be an anti-reflective coating or a photoresist layer.

In one embodiment, the initial protective layer 206 and the isolation structure 201 may be made of different materials. During a subsequent etching process to remove the portion of the initial protective layer 206 formed in the first region I on the base substrate 200 and the isolation structure 201, the etch rate on the initial protective layer 206 may be different from the etch rate on the isolation structure 201 such that the consumption of the isolation structure 201 in the first region I may be limited. In other embodiments, the initial protective layer and the isolation structure may be made of a same material.

In one embodiment, the thickness of the initial protective layer 206 may be in a range of approximately 10 Å to 30 Å. The reason to select such a range for the initial protective layer 206 lies in the following aspects. When the thickness of the initial protective layer 206 is too small, the initial protective layer 206 may not be able to provide sufficient protection for the portion of the isolation structure 201 formed in the second region during the process to remove the doped layer. However, when the thickness of the initial protective layer 206 is too large, removing the initial protective layer 206 in a subsequent process may become more difficult.

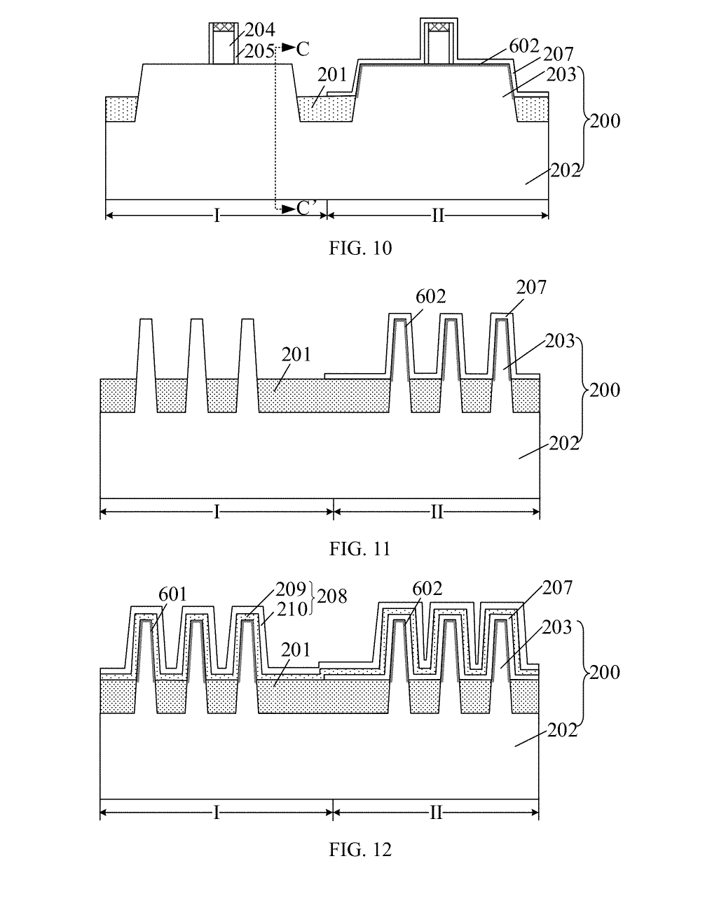

Further, returning to FIG. 14, the portion of the initial protective layer formed on the base substrate and the isolation structure in the first region may be removed to form a protective layer (S406). FIGS. 10-11 show schematic cross-section views of a corresponding semiconductor structure. FIG. 11 shows a cross-section view of the structure shown in FIG. 10 in a C-C′ direction.

Referring to FIGS. 10-11, the portion of the initial protective layer 206 (referring to FIG. 7) formed in the first region I on the base substrate 200 and the isolation structure 201 may be removed to form a protective layer 207. That is, the portion of the initial protective layer 206 formed in the second region II on the base substrate 200 and the isolation structure may become the protective layer 207. The process to remove the portion of the initial protective layer 206 formed in the first region I on the base substrate 200 and the isolation structure 201 may be, for example, an anisotropic dry etching process.

In one embodiment, the initial protective layer 206 is made of SiNₓ. Accordingly, the protective layer 207 may be made of SiNₓ. In other embodiments, the protective layer may be made of SiOₓ, SiON, germanium oxide, GeON, germanium nitride, or any other appropriate material. Alternatively, the protective layer may be an anti-reflective coating or a photoresist layer.

In one embodiment, the thickness of the protective layer 207 may be the same as the thickness of the initial protective layer 206. For example, the thickness of the protective layer 207 is in a range of approximately 15 Å to 40 Å.

In one embodiment, the initial protective layer 206 and the isolation structure are made of different materials. Therefore, during the process to etch the portion of the initial protective layer 206 formed in the first region I on the base substrate 200 and the isolation structure 201, the etch rate on the initial protective layer 206 may be different from the etch rate on the isolation structure 201. As a result, the damage to the isolation structure 201 during the etching process may be relatively light, and thus the performance of the semiconductor structure may be improved.

Further, returning to FIG. 14, a doped layer may be formed on the protective layer and also on the base substrate and the isolation structure in the first region, and then an annealing process may be performed on the doped layer 208 to allow the doping ions in the doped layer to diffuse into the base substrate in the first region and thus form a first doped region (S407). FIG. 12 shows a schematic cross-section view of a corresponding semiconductor structure.

Referring to FIG. 12, a doped layer 208 may be formed on the base substrate 200 and the isolation structure 201 in the first region I and also on the protective layer 207. Further, an annealing process may be performed on the doped layer 208 to allow the doping ions in the doped layer 208 to diffuse into the base substrate 200 in the first region I to form a first doped region 601. The first doped region 601 may be formed in a portion of each fin structure in the first region I, e.g., having a thickness from each sidewall of the fin structure. The first doped region 601 may be formed into each fin structure including the portion lower than a surface of the isolation structure 201 in the first region I. In some embodiments, doping ions in the doped layer 208 may be diffused into each entire fin structure in the first region I to form the first doped region 601.

The doped layer 208 may be formed by a process including the following steps. A first doped layer 209 may be deposited in the first region I on the base substrate 200 and the isolation structure 201 and also on the protective layer 207. After forming the first doped layer 209, a second doped layer 210 may be formed on the first doped layer 209. The first doped layer 209 and the second doped layer 210 may together form the doped layer 208.

In one embodiment, the first doped layer 209 may cover the base substrate 200 and the isolation structure 201 in the first region I, and also cover the protective layer 207. The second doped layer 210 may be formed on the top of the first doped layer 209.

In one embodiment, the first doped layer 209 may be formed by an ALD process. A reactant used in the ALD process may include a silicon precursor, an oxygen source, and a phosphor source. For example, the phosphor source may be PH₃. The process parameters of the ALD process may include a flow rate of PH₃ in a range of approximately 10 sccm to 1000 sccm, a reaction temperature in a range of approximately 80° C. to 300° C., a pressure in a range of approximately 5 mTorr to 20 mTorr, and a number of executed cycles in a range of approximately 5 times to 20 times. In other embodiments, the first doped layer may be formed by a CVD, PVD, or any other appropriate deposition process.

In one embodiment, the second doped layer 210 may be formed by an ALD process. A reactant used in the ALD process may include a silicon precursor, an oxygen source, and a boron source. For example, the boron source may be B₂H₅. The process parameters of the ALD process may include a flow rate of B₂H₅ in a range of approximately 5 sccm to 300 sccm, a reaction temperature in a range of approximately 80° C. to 300° C., a pressure in a range of approximately 5 mTorr to 30 mTorr, and a number of executed cycles in a range of approximately 5 times to 150 times. In other embodiments, the second doped layer may be formed by a CVD, PVD, or any other appropriate deposition process.

In one embodiment, the first region I is used to form NMOS transistors, and the first doped layer 209 may contain a plurality of doping ions. The doping ions may include phosphor ions. The concentration of the phosphor ions may be in a range of approximately 1.0E20 atm/cm³ to 1.0E22 atm/cm³.

In one embodiment the thickness of the first doped layer 209 may be in a range of approximately 10 Å to 50 Å. The second doped layer 210 may be used to prevent the doping ions in the first doped layer 209 from moving away from the fin structures 203 during a subsequent annealing process performed on the doped layer 208.

After performing the annealing process on the doped layer 208, the doping ions in the dope layer 208 may diffuse into the base substrate 200 in the first region I to form a first doped region 601. The first doped region 601 may be used to reduce the leakage current of the channel of the transistor, and thus reduce the short channel effect.

During the annealing process performed on the doped layer 208, when the annealing temperature is too low, the doping ions in the doped layer 208 may hardly diffuse into the base substrate 200 of the first region I. Therefore, forming the first doped region 601 may be difficult. However, when the annealing temperature is too high, the diffusion speed of the doped ions may be overly large so that controlling the thickness of the first doped region 601 may be difficult. In one embodiment, the annealing temperature may be in a range of approximately 950° C. to 1100° C.

During the annealing process performed on the doped layer 208, when the annealing time is too short, the doping ions in the doped layer 208 may hardly diffuse into the base substrate 200 of the first region I. Therefore, suppressing the short channel effect may be difficult. However, when the annealing time is too long, the thickness of the first doped region 601 may easily become too large so that the electrical performance of the transistor may be affected. Therefore, in one embodiment, the annealing time may be approximately 20 seconds or less.

During the annealing process performed on the doped layer 208, the doping ions in the first doped layer 209 may not diffuse into the base substrate 200 in the second region II. For example, the presence of the protective layer 207 between the base substrate 200 in the second region II and the first doped layer 209 may efficiently prevent the doping ions in the first doped layer 209 from diffusing into the base substrate 200 in the second region II.

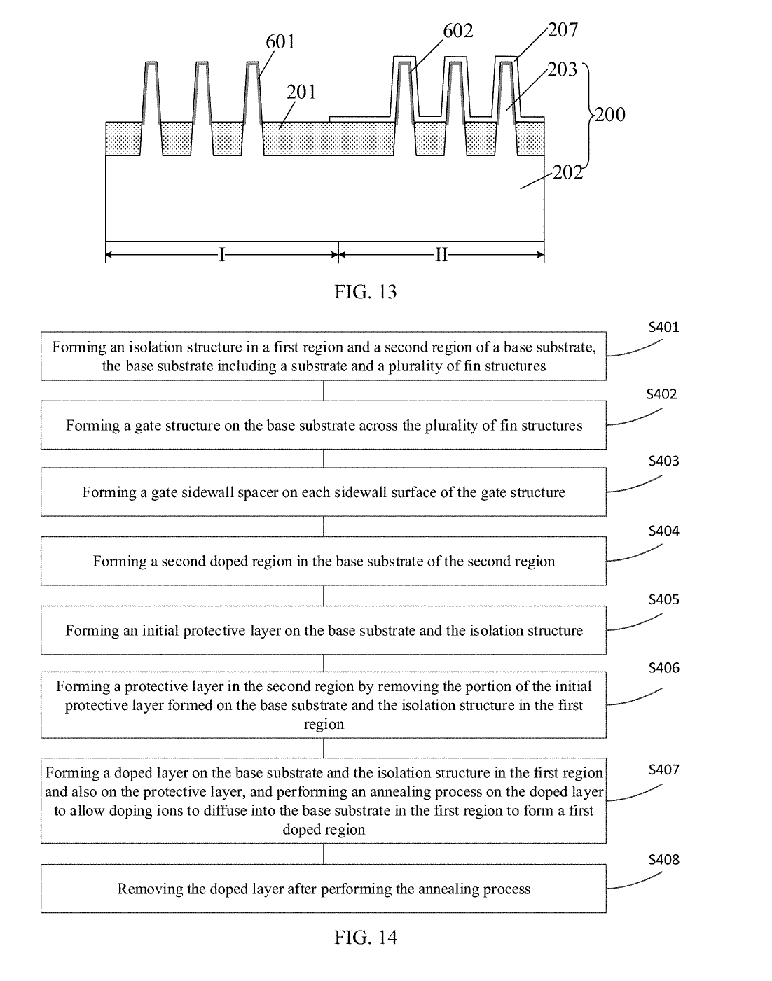

Further, returning to FIG. 14, after performing the annealing process on the doped layer, the doped layer may be removed (S408). FIG. 13 shows a schematic cross-section view of a corresponding semiconductor structure.

Referring to FIG. 13, after performing the annealing process on the doped layer 208, the doped layer 208 may be removed. During the process to remove the doped layer 208, the protective layer 207 may provide protection for the portion of the isolation structure 201 in the second region II so that the portion of the isolation structure formed in the second region II may not be etched. As such, the impact of the etching process on the isolation properties of the portion of the isolation structure 201 in the second region II may be reduced.

In one embodiment, the doped layer 208 may be removed by a wet etching process, a dry etching process, or an etching process combining both wet etching and dry etching.

According to the disclosed semiconductor structures and the fabrication methods, prior to forming the doped layer, a protective layer may be formed on the base substrate and the isolation structure formed in the second region. The protective layer may have two functions during the fabrication process. During a process to remove the doped layer, the protective layer may prevent the isolation structure in the second region becoming thinner, and may thus ensure that the thickness of the isolation structure formed on the base substrate in the second region is consistent with the thickness of the isolation structure formed on the base substrate in the first region. Therefore, the isolation properties of the isolation structure may be desired. As such, the leakage current in the semiconductor structure may be reduced, and the structural properties of the semiconductor structure may be improved.

Further, during an annealing process performed on the doped layer, the protective layer may prevent the doping ions from diffusing into the base substrate in the second region. Therefore, in some embodiments, the portion of the doped layer 208 formed in the second region may not need to be removed (not illustrated) prior to performing the annealing process on the doped layer. Instead, the doped layer 208 covering on the first region and the second region may be removed together, after performing the annealing process on the doped layer 208. As such, the semiconductor manufacturing technology may be simplified.

Further, the present disclosure also provides a semiconductor structure formed by the methods described above. FIG. 12 shows a schematic cross-section view of a corresponding semiconductor structure consistent with various embodiments of the present disclosure.

Referring to FIG. 12, the semiconductor structure may include a base substrate 200 including a first region I and a second region II. An isolation structure 201 may be formed on the base substrate 200.

The semiconductor structure may also include a first doped region 601 formed in the base substrate 200 of the first region I, and a protective layer 207 formed on the portion of the base substrate 200 and the isolation structure 201 in the second region II.

The base substrate 200 may also include a substrate 202 and a plurality of fin structures 203 formed on the substrate 202.

According to the disclosed semiconductor structure, a protective layer may be formed on the portion of the base substrate and the isolation structure in the second region to prevent reduction of the thickness of the isolation structure during the fabrication process. In addition, the protective layer may also prevent the doping ions in the doped layer from entering the second region. Therefore, the performance of the semiconductor structure may be improved.

Compared to existing fabrication methods and semiconductor structures, the disclosed fabrication methods and semiconductor structures may demonstrate advantages.

According to the disclosed fabrication methods for semiconductor structures, prior to forming the doped layer, a protective layer is formed on the portion of the base substrate and the isolation structure in the second region. The protective layer may have two functions during the fabrication process.

During a subsequent process to remove the doped layer, the protective layer prevents the isolation structure formed in the second region becoming thinner, and thus ensures that the thickness of the isolation structure formed in the second region is consistent with the thickness of the isolation structure formed in the first region. Therefore, the isolation properties of the isolation structure may be desired. As such, the leakage current in the semiconductor structure may be reduced, and the structural properties of the semiconductor structure may be improved.

Further, during an annealing process performed on the doped layer, the protective layer prevents the doping ions from diffusing into the base substrate in the second region. Therefore, the portion of the doped layer formed in the second region may not need to be removed prior to performing the annealing process on the doped layer; instead, the doped layer covering on the first region and the second region may be removed together after performing the annealing process on the doped layer covering the first and second regions. As such, the semiconductor manufacturing technology may be simplified.

According to the disclosed semiconductor structure, a protective layer formed on the base substrate and the isolation structure in the second region prevents the isolation structure in the second region becoming thinner and also prevents the doping ions in the doped layer from entering the second region. Therefore, the performance of the semiconductor structure may be improved.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a semiconductor structure, comprising:
forming an isolation structure on a base substrate including a first region and a second region;
forming a protective layer on the base substrate in the second region and on the isolation structure in the second region;
forming a doped layer on the base substrate in the first region and on the protective layer in the second region;
performing an annealing process on the doped layer to allow doping ions in the doped layer to diffuse into the first region of the base substrate and thus form a first doped region the first region of the base substrate; and
removing the doped layer after performing the annealing process.

2. The method for fabricating the semiconductor structure according to claim 1, wherein:
the base substrate includes a substrate and a plurality of fin structures formed on the substrate.

3. The method for fabricating the semiconductor structure according to claim 2, wherein forming the base substrate includes:
providing an initial substrate;
patterning the initial substrate to form the substrate and the plurality of fin structures on the substrate; and
forming the isolation structure on a portion of the substrate exposed between neighboring fin structures, wherein the isolation structure covers a portion of sidewall surfaces of each fin structure, and a top surface of the isolation structure is lower than a top surface of the fin structures.

4. The method for fabricating the semiconductor structure according to claim 1, wherein forming the protective layer includes:
forming an initial protective layer on the base substrate and the isolation structure;
removing a portion of the initial protective layer formed on the base substrate and the isolation structure in the first region to form the protective layer.

5. The method for fabricating the semiconductor structure according to claim 4, wherein:
a process to form the initial protective layer includes one of chemical vapor deposition (CVD), physical vapor deposition (PVD), and atomic layer deposition (ALD); and
a process to remove the portion of the initial protective layer formed on the base substrate and the isolation structure in the first region includes anisotropic dry etching.

6. The method for fabricating the semiconductor structure according to claim 1, wherein:
the protective layer is made of one of SiNₓ and SiON;
a thickness of the protective layer is in a range of approximately 15 Å to 40 Å.

7. The method for fabricating the semiconductor structure according to claim 2, prior to forming the protective layer, further including:
forming a gate structure across the plurality of fin structures, wherein,
the gate structure covers a portion of top and sidewall surfaces of each fin structure; and
the gate structure includes a gate dielectric layer and a gate electrode layer on the gate dielectric layer.

8. The method for fabricating the semiconductor structure according to claim 7, wherein:
a sidewall spacer is formed on each side of the gate structure.

9. The method for fabricating the semiconductor structure according to claim 1, wherein:
the doped layer includes a first doped layer and a second doped layer;
the first doped layer covers the protective layer in the second region and covers the base substrate and the isolation structure in the first region; and
the second doped layer is formed on the first doped layer.

10. The method for fabricating the semiconductor structure according to claim 9, wherein:
a thickness of the first doped layer is in a range of approximately 10 Å to 50 Å;
the first doped layer contains doping ions including phosphor ions; and
a concentration of the doping ions is in a range of approximately 1.0E20 atm/cm³ to 1.0E22 atm/cm³.

11. The method for fabricating the semiconductor structure according to claim 9, wherein:
the second doped layer is made of a material including SiOₓ; and
a thickness of the second doped layer is in a range of approximately 10 Å to 50 Å.

12. The method for fabricating the semiconductor structure according to claim 1, wherein:
the first region is used to form a plurality of N-type metal-oxide-semiconductor (NMOS) transistors; and
the second region is used to form a plurality of P-type metal-oxide-semiconductor (PMOS) transistors.

13. The method for fabricating the semiconductor structure according to claim 1, wherein:
a process to remove the doped layer includes dry etching or wet etching.

14. The method for fabricating the semiconductor structure according to claim 1, further including:
forming a second doped region in the second region.

15. The method for fabricating the semiconductor structure according to claim 14, wherein:
the second doped region is formed before forming the protective layer.

16. The method for fabricating the semiconductor structure according to claim 14, wherein:
the second doped region is formed after forming the first doped region.

17. The method for fabricating the semiconductor structure according to claim 14, wherein:
the second doped region is formed by an ion implantation process in the second region.

18. A semiconductor structure, comprising:
a base substrate including a first region and a second region;
an isolation structure formed on the base substrate;
a first doped region formed in the base substrate in the first region;
a protective layer formed on the base substrate and the isolation structure in the second region; and
a second doped region formed in the base substrate in the second region.

19. The semiconductor structure according to claim 18, wherein:
the base substrate includes a substrate and a plurality of fin structures formed on the substrate.

20. The semiconductor structure according to claim 17, wherein:
the protective layer is made of one of SiNₓ and SiON;
a thickness of the protective layer is in a range of approximately 15 Å to 40 Å.
